(19) United States
(12) Patent Application Publication
(10) Pub. No.: US 2025/0219031 A1
(43) Pub. Date: Jul. 3, 2025

(54) Semiconductor structure

(71) Applicant: UNITED MICROELECTRONICS CORP., Hsin-Chu City (TW)

(72) Inventors: Yi-Feng Hsu, Hsinchu City (TW); Shing-Ren Sheu, Hsinchu City (TW); Kai-Kuang Ho, Hsinchu City (TW); Yu-Jie Lin, Taichung City (TW)

(73) Assignee: UNITED MICROELECTRONICS CORP., Hsin-Chu City (TW)

(21) Appl. No.: 18/403,657

(22) Filed: Jan. 3, 2024

(30) Foreign Application Priority Data
Nov. 21, 2023 (TW) 112144882

(51) Int. Cl. H01L 25/16; H01L 23/00; H01L 23/14; H01L 23/48; H01L 23/498

(52) U.S. Cl. CPC H01L 25/162; H01L 23/14; H01L 23/481; H01L 23/49816; H01L 24/16; H01L 24/17; H01L 2224/16225; H01L 2224/17051; H01L 2924/19041

(57) ABSTRACT

The invention provides a semiconductor structure, which comprises a first substrate and a second substrate stacked with each other. A first passive element is located in the first substrate and a second passive element is located in the second substrate. A first wire layer is located on a top surface of the first substrate and electrically connected with the first passive element, and a conductive pad is located on a bottom surface of the second substrate and directly contacts the first wire layer.

### BACKGROUND OF THE INVENTION

### 1. Field of the Invention

The invention relates to the field of semiconductors, in particular to a semiconductor structure with stacked passive elements (such as deep trench capacitors).

### 2. Description of the Prior Art

With the development of semiconductor technology, the size of various electronic components is getting smaller and smaller. How to accommodate more electronic components in a limited unit space is the sustainable development direction and goal of this field. Capacitance structure has the function of storing charge, so it is often used to make one of the main components of various semiconductor electronic devices such as memory.

The conventional planar capacitor structure includes three layers, in which an insulating layer is sandwiched between two metal layers. However, with the development of technology, the requirements for the storage charge of capacitors are gradually increasing. If the manufacturer wants to make a capacitor that can store more charges, it need to increase the area of the capacitor, that is to say, increase the area of the metal layer and the insulating layer, but at the same time, the capacitor will occupy a larger area of the semiconductor device, which is not conducive to the miniaturization of the product.

### SUMMARY OF THE INVENTION

The invention provides a semiconductor structure, which comprises a first substrate and a second substrate stacked with each other, wherein a first passive element is located in the first substrate and a second passive element is located in the second substrate. A first wire layer is located on a top surface of the first substrate and electrically connected with the first passive element, and a first conductive pad is located on a bottom surface of the second substrate and directly contacts the first wire layer.

The invention also provides a semiconductor structure, which comprises a first substrate and a second substrate stacked with each other. A first passive element is located in the first substrate, and a second passive element is located in the second substrate. A first wire layer is located on a top surface of the first substrate and is electrically connected with the first passive element. A first conductive pad is located on a bottom surface of the second substrate, and a conductive bump is located between the first substrate and the second substrate and directly contacts the first wire layer and the first conductive pad.

The present invention is characterized by providing a stacked structure of semiconductor passive elements, such as deep trench capacitors (DTC). In order to improve the charge that can be accommodated by the capacitor structure in a cell, at least two or more substrates containing deep trench capacitors are stacked and electrically connected to each other. The stacking method may include stacking a plurality of substrates with a hybrid bond or a conductive bump. The structure provided by the invention is compatible with the current technologies, the size of the deep trench capacitor does not need to be redesigned, and since the area or height of each original deep trench capacitor is not changed, the problem that the occupied area is too large to affect other devices or the through silicon via is not easy to form due to the height is too large will not occur.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic cross-sectional structure of a passive element of the present invention.

FIG. 2 is a schematic cross-sectional view of a stacked structure of two passive elements according to an embodiment of the present invention.

FIG. 3 is a schematic cross-sectional view of a stacked structure of a plurality of passive elements according to an embodiment of the present invention.

FIG. 4 is a schematic sectional view of a stacked structure of two passive elements according to another embodiment of the present invention.

FIG. 5 is a schematic cross-sectional view of an electronic component according to an embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

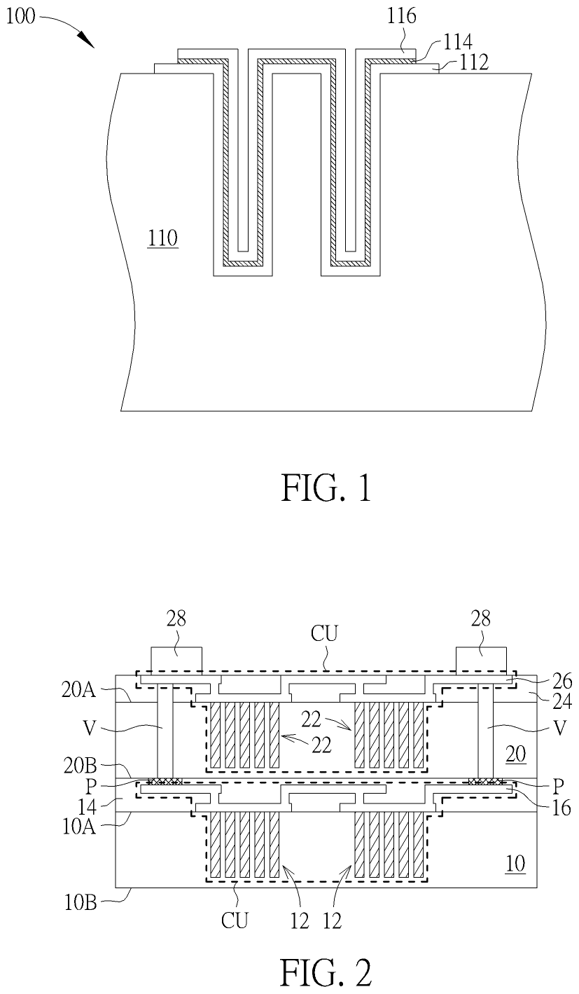

Please refer to FIG. 1, which shows a schematic cross-sectional structure of a passive element of the present invention. As shown in FIG. 1, a passive element 100 is provided, which is located in a substrate 110, such as a silicon substrate, the passive element described in this embodiment is, for example, a deep trench capacitor (DTC), and its manufacturing method includes forming a plurality of trenches on the substrate 110 by exposure, development and etching, the plurality of trenches are preferably arranged in parallel with each other. Then, a first electrode layer 112, an insulating layer 114 and a second electrode layer 116 are sequentially formed in the trench to form a deep trench capacitor. Subsequently, for example, a wire layer may be formed to electrically connect the passive element 100, and the wire layer is not drawn here for simplicity of the drawing. In this embodiment, the materials of the first electrode layer 112 and the second electrode layer 116 include conductive materials, such as metals, for example copper (Cu), chromium (Cr), titanium (Ti), tungsten (W), gold (Au), aluminum (Al), indium (In), tin (Sn), nickel (Ni), platinum (Pt) and silver (Ag) or alloys of the above materials, but not limited thereto. The material of the insulating layer 114 includes, but is not limited to, insulating materials such as silicon oxide, silicon nitride or silicon oxynitride. Therefore, the first electrode layer 112, the insulating layer 114 and the second electrode layer 116 constitute a deep trench capacitor. Compared with the general planar capacitor, the depth of the trench creates a larger capacitance area (that is, the inner sidewall and bottom surface of the trench can be regarded as a part of the capacitance area), so it has a larger capacitance value.

However, with the continuous progress of technology, the requirements for the capacitance value of electronic components have gradually increased. The passive element 100 (for example, deep trench capacitor) shown in the above-mentioned FIG. 1 may gradually face the situation that it is not enough to meet the use requirements. In order to increase the capacitance value of deep trench capacitor, there are two possible improvement directions, one of which is to increase the occupied area of deep trench capacitor (that is, to form more trenches and expand the plane area of deep trench capacitor), and the other is to increase the depth of each trench, that is, to form deeper trenches to increase the contact area of capacitor.

However, the above two possible ways to increase the capacitance have their limitations. Firstly, increasing the planar area of the capacitor will increase the occupied area of the capacitor structure in the whole semiconductor device, and may even reduce the formation space of other elements. On the other hand, if the depth of each trench is increased, the aspect ratio of each trench will also be increased, and the gap filling ability of each material layer will be reduced, which will enhance the difficulty of the process. In addition, while increasing the depth of the trench, it is also necessary to provide a thicker substrate 110. If the thickness of the substrate 110 is too large, it is not conducive to the formation of subsequent through silicon via (TSV) structures.

Therefore, the present invention provides a semiconductor structure, which can improve the overall capacitance value without changing the size of each passive element (such as deep trench capacitor), as shown in detail below.

Please refer to FIG. 2, which is a schematic cross-sectional view of a stacked structure of two passive elements according to an embodiment of the present invention. As shown in FIG. 2, a first substrate 10 and a second substrate 20 are provided, wherein the first substrate 10 includes a first passive element 12, and the second substrate 20 includes a second passive element 22. The first passive element 12 and the second passive element 22 are, for example, the deep trench capacitor shown in the above-mentioned FIG. 1, and the detailed structure includes a first electrode layer, an insulating layer and a second electrode layer stacked in the trench in sequence. In FIG. 2, the detailed structure of the deep trench capacitor is not drawn for simplicity, but the structure can refer to the structure shown in FIG. 1.

In this embodiment, the first substrate 10 and the second substrate 20 comprise silicon substrates, the first substrate 10 and the second substrate 20 are connected with each other by hybrid bond contact, so that the first passive element 12 and the second passive element 22 are electrically connected with each other. More specifically, the first substrate 10 includes a top surface 10A and a bottom surface 10B, and the second substrate 20 includes a top surface 20A and a bottom surface 20B, a first dielectric layer 14 disposed on the top surface 10A of the first substrate 10, which means that the first dielectric layer 14 contacts the top surface 10A of the first substrate 10 and the bottom surface 20B of the second substrate 20. In addition, a second dielectric layer 24 disposed on the top surface 20A of the second substrate 20. The materials of the first dielectric layer 14 and the second dielectric layer 24 described here include, for example, silicon oxide, silicon nitride or silicon oxynitride, but are not limited thereto.

In addition, the first wire layer 16 is located in the first dielectric layer 14, and a second wire layer 26 is located in the second dielectric layer 24. Besides, a conductive pad P is located in the first dielectric layer 14 and contacts the bottom surface 20B of the second substrate 20, and the contact plug V is located in the second substrate 20 and the second dielectric layer 24, and penetrates through the second substrate 20 and the second dielectric layer 24. The main materials of the first wire layer 16, the second wire layer 26, the conductive pad P and the contact plug V mentioned here include metals with good conductivity, such as copper (Cu), chromium (Cr), titanium (Ti), tungsten (W), gold (Au), aluminum (Al), indium (In), tin (Sn), nickel (Ni), platinum (Pt) and silver (Ag) or alloys of the above materials, but not limited thereto. The main purpose of forming the above elements is to electrically connect the first passive element 12 in the first substrate 10 to the second passive element 22 in the second substrate 20.

In more detail, as shown in FIG. 2, the first wire layer 16 is located on the top surface 10A of the first substrate 10, directly contacting and electrically connecting the first passive element 12. Similarly, the second wire layer 26 is located on the top surface 20A of the second substrate 20, directly contacting and electrically connecting the second passive element 22. The conductive pad P is in direct contact and electrical connection with the first wire layer 16, the contact plug V is in direct contact and electrical connection with the second wire layer 26, and the conductive pad P is in direct contact and electrical connection with the contact plug V. Therefore, the first passive element 12 and the second passive element 22 can be electrically connected to each other through the first wire layer 16, the second wire layer 26, the conductive pad P and the contact plug V. If the first passive element 12 and the second passive element 22 are deep trench capacitors, they can be electrically connected in parallel and their capacitance values can be added, that is to say, an element with a larger capacitance value can be formed in a limited space.

In addition, in FIG. 2, a conductive bump 28 can be formed on the top surface of the second wire layer 26. The conductive bump 28 can be used to electrically connect the first passive element 12 and the second passive element 22 connected in parallel with other elements, for example, it can be electrically connected with a subsequent chip including a processor or a memory. In addition, the above-mentioned first wire layer 16 is electrically connected to the first passive element 12, which means that the wires in the first wire layer 16 are electrically connected to the first electrode layer (the lower electrode) and the second electrode layer (the upper electrode) of the first passive element 12 respectively. Similarly, the second wire layer 26 is electrically connected to the second passive element 22, which means that the wires in the second wire layer 26 are electrically connected to the first electrode layer (the lower electrode) and the second electrode layer (the upper electrode) of the second passive element 22 respectively, and then the first wire layer 16 and the second wire layer 26 are directly or indirectly electrically connected to the conductive bumps 28 or other voltage sources for the capacitor structure to store charges.

In FIG. 2, the first passive element 12 and the second passive element 22 included in the first substrate 10 and the second substrate 20 are electrically connected to each other. Here, a capacitor unit CU can be defined first, each capacitor unit at least includes a part of the substrate, a passive element, a part of the dielectric layer and wires. That is, in the structure shown in FIG. 2, it can be regarded that two capacitor units CU are stacked and electrically connected with each other. More specifically, the first substrate 10, the first passive element 12, the first dielectric layer 14 and the first conductor layer 16 can be regarded as one capacitor unit CU, while the second substrate 20, the second passive element 22, the second dielectric layer 24 and the second conductor layer 26 can be regarded as another capacitor unit CU, and these two stacked capacitor units CU can be electrically connected with the contact plug V through the conductive pad P. In addition, in other embodiments, more capacitor units CU can be stacked, for example, another conductive pad P can be formed above the second wire layer 26 without forming the conductive bump 28, so that other capacitor units (not shown) can be stacked above the second substrate 20.

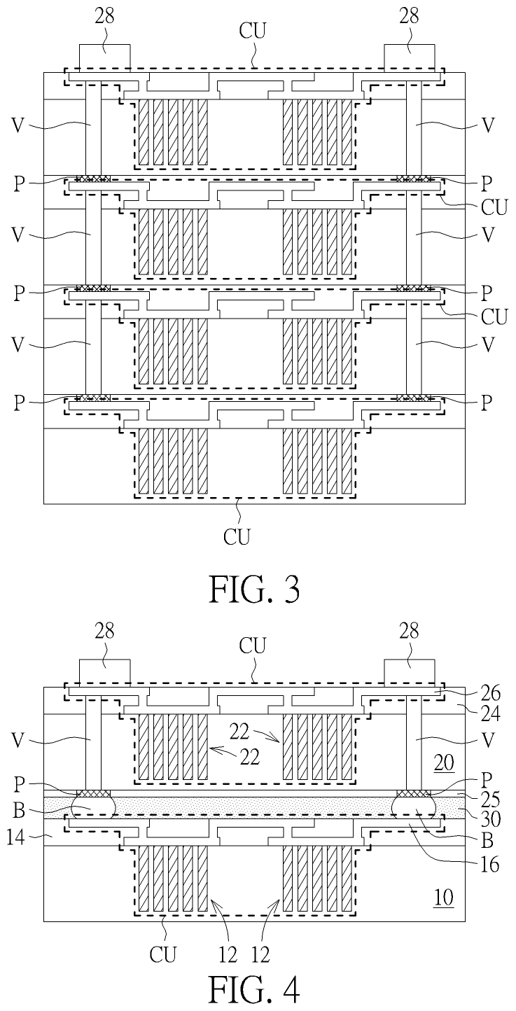

For example, FIG. 3 is a schematic cross-sectional view of a stacked structure of a plurality of passive elements according to an embodiment of the present invention. In this embodiment, most of the elements are the same as those shown in the above-mentioned FIG. 2. In this embodiment, more capacitor units CU can be stacked and electrically connected with each other, the internal structure of each capacitor unit CU is similar or the same as that shown in FIG. 2, and the other same elements are not repeated here. In addition, for the sake of simplicity, some elements in FIG. 3 are not marked with reference symbols, but these elements belong to the capacitor unit CU, and their detailed structures can refer to FIG. 2. According to the concepts shown in FIG. 2 and FIG. 3, the structure provided by the invention can stack more passive elements on each other as required, and improve the efficiency of products without changing the size of their respective products and occupying more area.

It is worth noting that in the above embodiment, the contact plug V directly contacts the conductive pad P to achieve the effect of electrical connection. This technology of direct contact between conductive pads and other adjacent components (such as wires) is also called hybrid bond technology. Hybrid bond technology allows higher density components to be bonded with each other. In this embodiment, hybrid bond contacts are combined with multiple deep trench capacitors, so that the passive elements (such as the deep trench capacitors) can be stacked and electrically connected with each other. When the passive elements are deep trench capacitors, the capacitance values of the deep trench capacitors can be added.

The following description will detail the different embodiments of the semiconductor structure and the manufacturing method of the present invention. To simplify the description, the following description will detail the dissimilarities among the different embodiments and the identical features will not be redundantly described. In order to compare the differences between the embodiments easily, the identical components in each of the following embodiments are marked with identical symbols.

In addition to stacking and electrically connecting passive elements with hybrid bond technology, the invention can also stack and electrically connect passive elements with each other in other methods. For example, FIG. 4 is a schematic cross-sectional view of a stacked structure of two passive elements according to another embodiment of the present invention. Compared with the first embodiment, this embodiment also includes a first substrate 10 and a second substrate 20 stacked with each other, the first substrate 10 includes a first passive element 12 (such as a deep trench capacitor) and the second substrate 20 includes a second passive element 22 (such as a deep trench capacitor), and the first passive element 12 and the second passive element 22 are electrically connected with each other. Most of the elements not mentioned in this embodiment are similar or same as those shown in FIG. 2, so the same elements are not repeated here.

The difference between this embodiment and the embodiment shown in FIG. 2 is that the two substrates are not bonded to each other by hybrid bond technology, but are connected to each other by conductive bump. In more detail, referring to FIG. 4, a bottom dielectric layer 25 is formed on the bottom surface 20B of the second substrate 20, and the material of the bottom dielectric layer 25 is, for example, but not limited to, silicon oxide. And the conductive pad P is formed in the bottom dielectric layer 25. In addition, in this embodiment, the conductive bump B is located between the first substrate 10 and the second substrate 20, more specifically, between the first dielectric layer 14 and the bottom dielectric layer 25. As seen from FIG. 4, the conductive bump B directly contacts the upper conductive pad P and the lower first wire layer 16. Therefore, the first passive element 12 and the second passive element 22 can be electrically connected to each other through the paths of the first conductive layer 16, the conductive bump B, the conductive pad P, the conductive plug V and the second conductive layer 26. In addition, a filling layer 30 is further included between the first dielectric layer 14 and the bottom dielectric layer 25, and the material of the filling layer 30 may include epoxy, but it is not limited to this. The filling layer 30 may be filled from the gap on the side of the device by capillary phenomenon, so as to fix the conductive bump B and improve the stability of the structure.

In addition, in the embodiment shown in FIG. 4, two substrates are bonded with the conductive bumps B, and the passive elements in the two substrates are electrically connected with each other. In other embodiments of the present invention, more substrates (more than two substrates) and their respective passive elements can be stacked and electrically connected with each other through the conductive bumps B. That is, it is similar to the embodiment shown in FIG. 3, but the multiple passive elements are electrically connected by the conductive bumps B instead of the hybrid bond technology. This variation is also within the scope of the present invention.

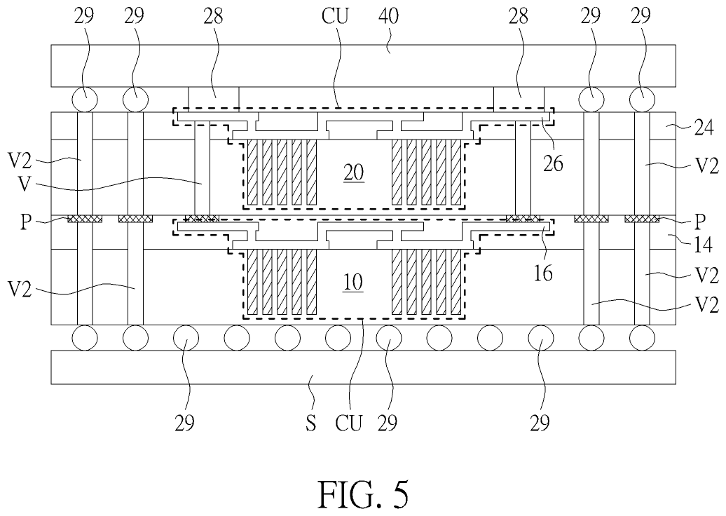

In practical application, the structure of the embodiment shown in FIG. 2, FIG. 3 or FIG. 4 can be formed on a circuit substrate, and then other electronic components such as memories or chips can be connected to the capacitor structure. As shown in FIG. 5, FIG. 5 shows a schematic cross-sectional structure of an electronic component according to an embodiment of the present invention. The structure shown in FIG. 5 includes two capacitor units CU which are stacked and electrically connected with each other, and this part of the structure is basically the same as that shown in FIG. 2, so it will not be repeated here. In this embodiment, two capacitor units CU as shown in FIG. 2 are formed on a circuit substrate S, and further include an electronic component 40 located on the capacitor units CU above and electrically connected with the capacitor units CU. More specifically, the circuit substrate S described here is, for example, a printed circuit board (PCB) used in this field, and its material is, for example, glass fiber and plastic, which means that the material of the circuit substrate S is different from the material of the first substrate 10 or the second substrate 20 (for example, silicon). In addition, the electronic component 40 is, for example, a chip, such as a system on chip including processors and memories, but not limited thereto. The electronic component 40 can be electrically connected with the capacitor units CU through the conductive bumps 28 shown in FIG. 2, and the lower circuit board S can be electrically connected with the capacitor unit CU through other conductive bumps 29. The conductive bumps 28 and the conductive bumps 29 described here are, for example, solder bump or wire layers, but are not limited thereto.

Therefore, in the present invention, the first substrate 10 and the second substrate 20 are arranged between the circuit substrate S (such as a printed circuit board) and the electronic component 40 (such as a chip) and can be used as an interposer between them. In the general technology, the interposer includes a conductive wire layers or conductive plugs for conducting current, and its function is to connect the pin of a tiny chip to the pin of a larger circuit board, which usually does not include other components. A feature of this embodiment is that the interposer (the first substrate 10 and the second substrate 20) contains a capacitor unit CU and the conductive plugs V2 for connecting the upper electronic component 40 and the lower circuit substrate S, the conductive plug V2 electrically connects the conductive bump 29 (such as a solder bump) with the electronic component 40 or the circuit substrate S. In other words, the first substrate 10 and the second substrate 20 in the present invention are used as an interposer layer, so they do not include active devices such as transistors.

The stacked structure of the capacitor units CU included in the embodiment shown in FIG. 5 is the same as that shown in FIG. 2, but it can be understood that the stacked structure of the capacitor unit CU in other embodiments of the present invention can also be applied to the embodiments shown in FIGS. 3-4, that is, the stacked structure of the capacitor units CU in each embodiment can connect the circuit substrate S and the electronic component 40 respectively, and all the above embodiments are within the scope of the present invention.

In addition, it is worth noting that in various embodiments of the present invention, passive elements are all formed in a silicon substrate, that is, in the actual manufacturing process, passive elements can be manufactured on the same wafer (the silicon substrate) to form a plurality of passive elements such as deep trench capacitors, and then the wafer is cut to form a substrate containing passive elements similar to that shown in FIG. 1. Subsequently, these substrates are stacked on each other and electrically connected. In other words, in various embodiments of the present invention, the first passive element 12, the second passive element 22 or other passive elements with the same structure can be formed at the same time in the same process step. Therefore, each passive element preferably has the same size, and since the size of each deep trench capacitor can be the same as that of the prior art, there is no need to change the area or depth of each deep trench capacitor, so that the problem that the yield of semiconductor devices is reduced due to the over-occupied area or the deep capacitance can be avoided.

Based on the above description and drawings, the present invention provides a semiconductor structure, which comprises a first substrate 10 and a second substrate 20 stacked with each other. A first passive element 12 is located in the first substrate 10 and a second passive element 22 is located in the second substrate 20. A first wire layer 16 is disposed on a top surface 10A of the first substrate 10 and electrically connected to the first passive element 12. A conductive pad (the conductive pad P located between the first wire layer 16 and the second substrate 20 in FIG. 2) is located on a bottom surface 20B of the second substrate 20 and directly contacting the first wire layer 16 (please refer to the structure shown in FIG. 2).

In some embodiments of the present invention, the first substrate 10 and the second substrate 20 comprise silicon substrates.

In some embodiments of the present invention, the first passive element 12 and the second passive element 22 include deep trench capacitors.

In some embodiments of the present invention, the deep trench capacitor comprises a first electrode layer 112, an insulating layer 114 and a second electrode layer 116, which are located in a plurality of parallel trenches in the first substrate 10 or the second substrate 20.

In some embodiments of the present invention, a first dielectric layer 14 is located between the first substrate 10 and the second substrate 20, and the first wire layer 16 and the conductive pad P are located in the first dielectric layer 14.

In some embodiments of the present invention, a circuit substrate S is further included, which is located below the first substrate 10 and electrically connected with the first passive element 12.

In some embodiments of the present invention, an electronic component 40, such as a chip, is located above the second substrate 20 and electrically connected to the second passive element 22.

In some embodiments of the present invention, there is further included a conductive plug V penetrating through the second substrate 20 and electrically connected with the conductive pad P.

In some embodiments of the present invention, a second wire layer 26 is located on the top surface of the second substrate 20, and the second wire layer 26 is electrically connected to the second passive element 22 and the conductive plug V.

The present invention further provides a semiconductor structure, which comprises a first substrate 10 and a second substrate 20 stacked with each other. A first passive element 12 is disposed in the first substrate 10 and a second passive element 22 is disposed in the second substrate 20. A first wire layer 16 is disposed on a top surface 10A of the first substrate 10, and the first wire layer 16 is electrically connected to the first passive element 12. A conductive pad (the conductive pad P between the conductive bump B and the second substrate 20 in FIG. 4) is located on a bottom surface 20B of the second substrate 20, and a conductive bump B is located between the first substrate 10 and the second substrate 20, and directly contacts the first wire layer 16 and the conductive pad P (please also refer to the structure shown in FIG. 4).

In some embodiments of the present invention, a first dielectric layer 14 is further included, which is located on the top surface 10A of the first substrate 10, the first wire layer 16 is located in the first dielectric layer 14.

In some embodiments of the present invention, a bottom dielectric layer 25 is further included, which is located on the bottom surface 20B of the second substrate 20, the conductive pad P is located in the bottom dielectric layer 25.

In some embodiments of the present invention, a filling layer 30 is further included, which is located between the first dielectric layer 10 and the bottom dielectric layer 25, the conductive bump B is located in the filling layer 30.

In some embodiments of the present invention, a conductive plug V penetrates through the second substrate 20, and the conductive plug V is electrically connected with the conductive bump B through the conductive pad P.

In some embodiments of the present invention, a second wire layer 26 is located on a top surface 20A of the second substrate 20, wherein the second wire layer 26 is electrically connected to the conductive plug V.

The present invention is characterized by providing a stacked structure of semiconductor passive elements, such as deep trench capacitors (DTC). In order to improve the charge that can be accommodated by the capacitor structure in a cell, at least two or more substrates containing deep trench capacitors are stacked and electrically connected to each other. The stacking method may include stacking a plurality of substrates with a hybrid bond or a conductive bump. The structure provided by the invention is compatible with the current technologies, the size of the deep trench capacitor does not need to be redesigned, and since the area or height of each original deep trench capacitor is not changed, the problem that the occupied area is too large to affect other devices or the through silicon via is not easy to form due to the height is too large will not occur.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a first substrate and a second substrate stacked with each other;
a first passive element located in the first substrate and a second passive element is located in the second substrate;
a first wire layer located on a top surface of the first substrate and electrically connected to the first passive element; and
a first conductive pad located on a bottom surface of the second substrate and directly contacting the first wire layer.

2. The semiconductor structure according to claim 1, wherein the first substrate and the second substrate comprise silicon substrates.

3. The semiconductor structure according to claim 1, wherein the first passive element and the second passive element comprise deep trench capacitors.

4. The semiconductor structure according to claim 3, wherein the deep trench capacitor comprises a first electrode layer, an insulating layer and a second electrode layer, which are located in a plurality of parallel trenches in the first substrate or the second substrate.

5. The semiconductor structure according to claim 1, further comprising a first dielectric layer between the first substrate and the second substrate, wherein the first wire layer and the first conductive pad are located in the first dielectric layer.

6. The semiconductor structure according to claim 1, further comprising a circuit substrate located below the first substrate and electrically connected with the first passive element.

7. The semiconductor structure according to claim 1, further comprising a chip located above the second substrate and electrically connected to the second passive element.

8. The semiconductor structure according to claim 1, further comprising a conductive plug penetrating through the second substrate and electrically connected to a second conductive pad.

9. The semiconductor structure according to claim 8, further comprising a second wire layer on the top surface of the second substrate, wherein the second wire layer is electrically connected with the second passive element and the conductive plug.

10. A semiconductor structure, comprising:
a first substrate and a second substrate stacked with each other;
a first passive element located in the first substrate and a second passive element located in the second substrate;
a first wire layer located on a top surface of the first substrate and electrically connected to the first passive element;
a first conductive pad located on a bottom surface of the second substrate; and
a conductive bump located between the first substrate and the second substrate and directly contacts the first wire layer and the first conductive pad.

11. The semiconductor structure according to claim 10, wherein the first substrate and the second substrate comprise silicon substrates.

12. The semiconductor structure according to claim 10, wherein the first passive element and the second passive element comprise deep trench capacitors.

13. The semiconductor structure according to claim 12, wherein the deep trench capacitor comprises a first electrode layer, an insulating layer and a second electrode layer, which are located in a plurality of parallel trenches in the first substrate or the second substrate.

14. The semiconductor structure according to claim 10, further comprising a first dielectric layer located on the top surface of the first substrate, wherein the first wire layer is located in the first dielectric layer.

15. The semiconductor structure according to claim 14, further comprising a bottom dielectric layer located on the bottom surface of the second substrate, wherein the first conductive pad is located in the bottom dielectric layer.

16. The semiconductor structure according to claim 15, further comprising a filling layer located between the first dielectric layer and the bottom dielectric layer, wherein the conductive bump is located in the filling layer.

17. The semiconductor structure according to claim 10, further comprising a circuit substrate located below the first substrate and electrically connected with the first passive element.

18. The semiconductor structure according to claim 10, further comprising a chip located above the second substrate and electrically connected with the second passive element.

19. The semiconductor structure according to claim 10, further comprising a conductive plug penetrating through the second substrate, and the conductive plug is electrically connected with the conductive bump through the first conductive pad.

20. The semiconductor structure according to claim 19, further comprising a second wire layer on a top surface of the second substrate, wherein the second wire layer is electrically connected to the conductive plug.
